(19) United States
(12) Patent Application Publication
(10) Pub. No.: US 2014/0185254 A1
(43) Pub. Date: Jul. 3, 2014

(54) PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Jee Soo MOK, Suwon (KR); Jong Seok BAE, Suwon (KR); Soon Jin CHO, Suwon (KR); Duck Young MAENG, Suwon (KR)

(73) Assignee: SAMSUNG ELECTRO-MECHANICS CO., LTD., Suwon (KR)

(21) Appl. No.: 13/845,020

(22) Filed: Mar. 17, 2013

(30) Foreign Application Priority Data
Dec. 27, 2012 (KR) 10-2012-0154684

(51) Int. Cl. H05K 1/02; H05K 3/30; H05K 3/34

(52) U.S. Cl. CPC H05K 1/02; H05K 3/3452; H05K 3/30
USPC 361/760; 174/250; 29/846; 29/832

(57) ABSTRACT

Disclosed herein is a printed circuit board including: a base substrate in which a connection pad is formed; a solder resist layer formed on the base substrate and comprising a trench exposing a surface of the base substrate; and a dam formed on the solder resist layer and burying the inside of the trench.

### CROSS REFERENCE TO RELATED APPLICATION

This application claims the benefit of Korean Patent Application No. 10-2012-0154684, filed on Dec. 27, 2012, entitled “Printed Circuit Board and Method of Manufacturing the Same”, which is hereby incorporated by reference in its entirety into this application.

### BACKGROUND OF THE INVENTION

1. Technical Field The present invention relates to a printed circuit board and a method of manufacturing the same.

2. Description of the Related Art

As electronic devices have been recently thin, small size, and highly functional, a packaging technology of loading electronic devices on substrates requires high density mounting, and accordingly, a mounting technology of a chip scale package form appears.

In a case where an electronic device is mounted on a printed circuit board, a connection between the printed circuit board and the electronic device is reinforced by filling a gap formed between the electronic device and the printed circuit board with an underfill so as to secure connection reliability of the electronic device (U.S. Pat. No. 8,039,761). In a case where such an underfill is liquid resin and is injected into the gap between the printed circuit board and the electronic device, a predetermined amount of the underfill is ejected to a peripheral portion.

However, since the electronic device tends to be mounted on the printed circuit board at high density and a circuit pattern tends to be formed at high density according to a recent development of the electronic device, in a case where the underfill is ejected to an approaching connection pad or circuit pattern, the connection pad or the circuit pattern is contaminated, which causes a defective product.

### SUMMARY OF THE INVENTION

The present invention has been made in an effort to provide a printed circuit board that forms a dam having an enhanced adhesion and a method of manufacturing the same.

According to a first preferred embodiment of the present invention, there is provided a printed circuit board including: a base substrate in which a connection pad is formed; a solder resist layer formed on the base substrate and comprising a trench exposing a surface of the base substrate; and a dam formed on the solder resist layer and burying the inside of the trench.

A roughness may be formed in an upper portion of the solder resist layer and an inner wall of the trench.

The surface of the base substrate exposed by the trench may expose at least one of an insulation layer and a circuit pattern of the base substrate.

The solder resist layer may further include an opening portion exposing the connection pad to the outside.

The printed circuit board may further include: a bump formed on the connection pad.

The printed circuit board may further include: an electronic device mounted on the bump.

The printed circuit board may further include: underfill resin injected between the electronic device and the base substrate.

An upper portion of the dam may be formed in a semispherical shape.

According to a second preferred embodiment of the present invention, there is provided a method of manufacturing a printed circuit board, the method including: providing a base substrate in which a connection pad is formed; forming a solder resist layer comprising a trench exposing a surface of the base substrate on the base substrate; and forming a dam on the solder resist layer and burying the inside of the trench.

The forming of the solder resist layer may include: stacking the solder resist layer on the base substrate; and removing the solder resist layer from a location at which the dam is to be formed and forming the trench exposing the surface of the base substrate.

The method may further include: after the forming of the solder resist layer, forming a bump on the connection pad.

The method may further include: before the forming of the bump, forming an opening portion in the solder resist layer so as to allow the connection pad to be exposed to the outside.

The method may further include: after the forming of the solder resist layer, forming a roughness in an upper portion of the solder resist layer and an inner wall of the trench.

In the forming of the roughness, the roughness may be formed using a plasma polishing method or a chemical polishing method.

In the forming of the dam, the dam may be formed by filling and curing the inside of the trench with dam ink.

The method may further include: after the forming of the bump, mounting an electronic device on the bump.

The method may further include: injecting underfill resin between the electronic device and the base substrate.

In the forming of the dam, the dam ink may be filled inside the trench using an inkjet printing method.

An upper portion of the dam may be formed in a semispherical shape.

In the forming of the solder resist layer, the surface of the base substrate exposed by the trench may expose at least one of an insulation layer and a circuit pattern of the base substrate.

### BRIEF DESCRIPTION OF THE DRAWINGS

The above and other features and advantages of the present invention will become more apparent by describing in detail exemplary embodiments thereof with reference to the attached drawings in which:

FIG. 1 is an exemplary view of a printed circuit board according to an embodiment of the present invention;

FIGS. 2 through 8 are exemplary views for explaining a method of manufacturing a printed circuit board according to an embodiment of the present invention;

FIG. 9 is an exemplary view of a printed circuit board in which a dam is formed according to an embodiment of the prior art;

FIG. 10 is an exemplary view of a printed circuit board in which a dam is formed according to another embodiment of the prior art; and

FIG. 11 is an exemplary view of a printed circuit board in which a dam is formed according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

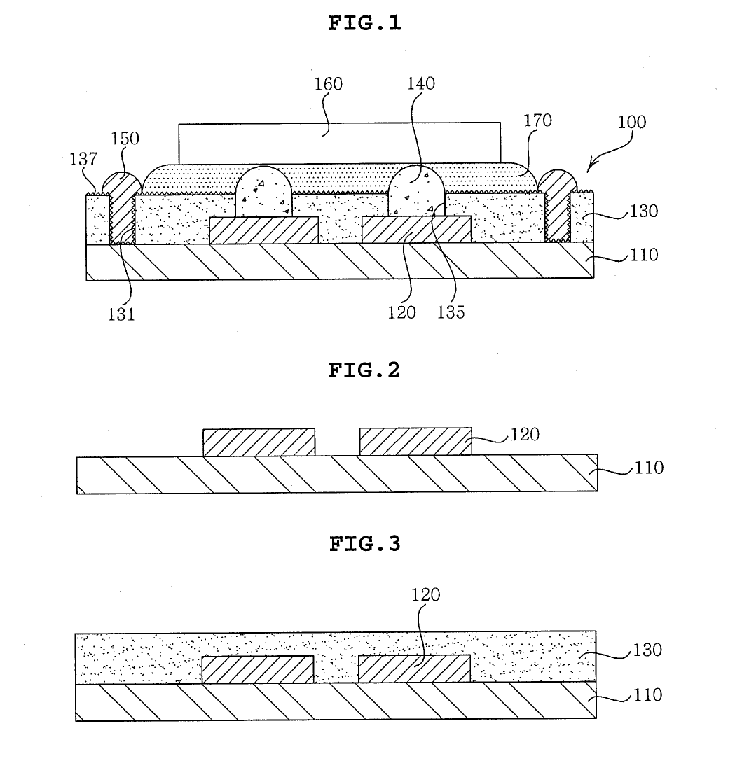

FIG. 1 is an exemplary view of a printed circuit board 100 according to an embodiment of the present invention.

Referring to FIG. 1, the printed circuit board 100 may include a base substrate 110, a solder resist layer 130, a dam 150, a bump 140, and underfill resin 170.

The base substrate 110 may be usually complex polymer resin used as an interlayer insulation material. For example, the printed circuit board 100 may be manufactured to be thinner by employing prepreg as the base substrate 110. Alternatively, a fine circuit may be easily implemented by employing an Ajinomoto build up film (ABF) as the base substrate 110. In addition, the base substrate 110 may use epoxy based resin such as FR-4, Bismaleimide Triazine (BT), etc., but is not particularly limited thereto. A copper clad laminate (CCL) may be used as the base substrate 110.

In the present embodiment, the base substrate 110 may include the connection pad 120. The connection pad 120 may be an element that is electrically connected to an external electronic device 160. The connection pad 120 may be formed of electrically conductive metal. A circuit layer such as a circuit pattern (not shown) and a via (not shown) as well as the connection pad 120 may be formed on the base substrate 110.

Meanwhile, although the base substrate 110 is configured as a single layer in FIG. 1, the present invention is not limited thereto. That is, the base substrate 110 may be a build-up layer consisting of an insulation layer and a circuit layer of a multilayer or a monolayer and the via.

The solder resist layer 130 may be formed on the base substrate 110. The solder resist layer 130 may be formed so as to prevent the circuit layer from being damaged during soldering for mounting the electronic device 160 on the base substrate 110.

An opening portion 135 and a trench 131 may be formed in the solder resist layer 130. The opening portion 135 may be formed in an upper portion of the connection pad 120. The opening portion 135 may allow the connection pad 120 to be exposed from the solder resist layer 130.

The trench 131 may be formed passing through the solder resist layer 130. The trench 131 may allow a surface of the base substrate 110 to be exposed from the solder resist layer 130. An area of the base substrate 110 exposed by the trench 131 may be the insulation layer formed of the interlayer insulation material. Alternatively, the area of the base substrate 110 exposed by the trench 131 may be the circuit layer formed of the electrically conductive metal. Alternatively, the trench 131 may concurrently expose the insulation layer and the circuit layer of the base substrate 110. The trench 131 may be formed outside of the connection pad 120 to surround the connection pad 120. That is, the trench 131 may be formed to surround the outside of the electronic device 160 that will be mounted later.

Also, a roughness may be formed in a surface of the solder resister layer 130. That is, the roughness may be formed in both an upper portion of the solder resist layer 130 and an inner wall of the trench 131.

The dam 150 may be formed inside the trench 131 and the upper portion of the solder resist layer 130. The dam 150 is an element to prevent underfill resin 170 injected between the electronic device 160 that will be mounted later and the base substrate 110 from being ejected to the outside. The dam 150 may be formed outside the printed circuit board 100. For example, the dam 150 may be formed outside the electronic device 160 that will be mounted later to surround the electronic device 160. The dam 150 may be formed of a solder resist material. The dam 150 may be formed by filling and hardening the trench 131 with dam ink using an inkjet printing method. The dam 150 formed using the inkjet printing method may have a hemispherical shape with an upper portion convex and curved.

The bump 140 may be formed on the connection pad 120. That is, the bump 140 may be formed on the connection pad 120 exposed from the solder resist layer 130. The electronic device 160 may be mounted on the bump 140. The bump 140 may bond the connection pad 120 and the electronic device 160 and electrically connect the connection pad 120 and the electronic device 160.

The underfill resin 170 may be injected between the electronic device 160 and the base substrate 110. The underfill resin 170 may function as an adhesive agent for fixing the electronic device 160 to the printed circuit board 100. The underfill resin 170 may function as protecting the electronic device 160 and the printed circuit board 100 from an external shock.

According to an embodiment of the present invention, the dam 150 may be formed by forming the trench 131 that passes through the solder resist layer 130 and burying the inside of the trench 131. In this regard, the roughness may be formed on the upper portion of the solder resist layer 130 and the inner wall of the trench 131. The dam 150 is formed in this way, and thus a bonding area between the dam 150, the solder resist layer 130, and the base substrate 110 may be maximized. That is, the bonding area between the dam 150 and the printed circuit board 100 is maximized, and thus reliability may be also enhanced.

Method of Manufacturing Printed Circuit Board

FIGS. 2 through 8 are exemplary views for explaining a method of manufacturing the printed circuit board 100 according to an embodiment of the present invention. Referring to FIG. 2, the base substrate 110 may be provided. The base substrate 110 may be usually complex polymer resin used as an interlayer insulation material. For example, the printed circuit board 100 may be manufactured to be thinner by employing prepreg as the base substrate 110. Alternatively, a fine circuit may be easily implemented by employing an Ajinomoto build up film (ABF) as the base substrate 110. In addition, the base substrate 110 may use epoxy based resin such as FR-4, Bismaleimide Triazine (BT), etc., but is not particularly limited thereto. A copper clad laminate (CCL) may be used as the base substrate 110.

In the present embodiment, the base substrate 110 may include the connection pad 120. The connection pad 120 may be an element that is electrically connected to an external electronic device (160 of FIG. 8). The connection pad 120 may be formed of electrically conductive metal. A circuit layer such as a circuit pattern (not shown) and a via (not shown) as well as the connection pad 120 may be formed on the base substrate 110.

Meanwhile, although the baser substrate 110 is configured as a single layer in FIG. 2, the present invention is not limited thereto. That is, the base substrate 110 may be a build-up layer consisting of an insulation layer and a circuit layer of a multilayer or a monolayer and the via. Referring to FIG. 3, the solder resist layer 130 may be formed on the base substrate 110. The solder resist layer 130 may be formed to surround the connection pad 120 formed in the base substrate 110.

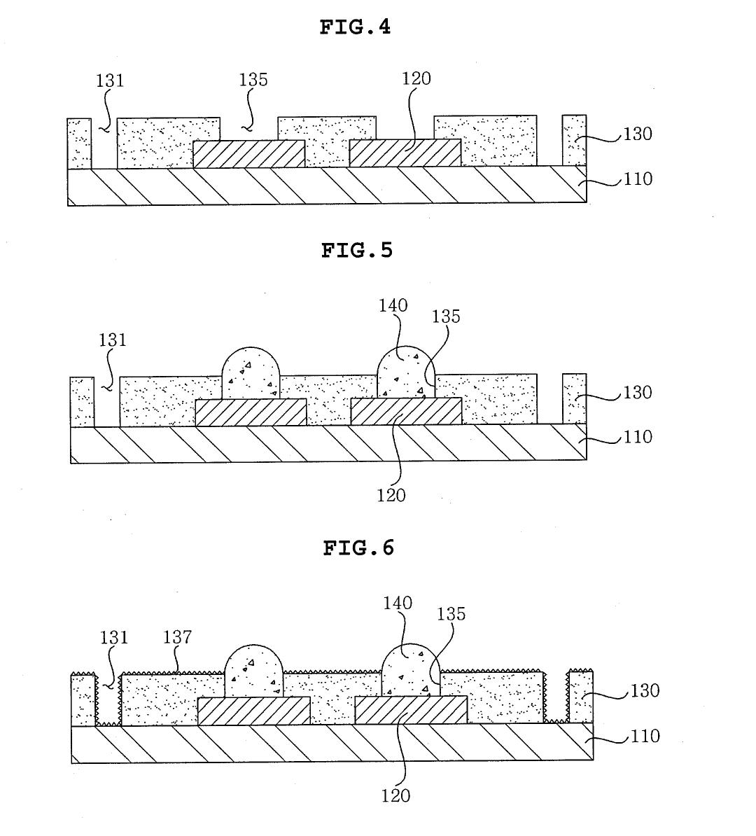

Referring to FIG. 4, the trench 131 and the an opening portion 135 may be formed in the solder resist layer 130. The trench 131 may be formed passing through the solder resist layer 130. That is, the base substrate 110 may be exposed in a lower surface of the trench 131. In this regard, an area of the base substrate 110 exposed by the trench 131 may be the insulation layer formed of the interlayer insulation material. Alternatively, the area of the base substrate 110 exposed by the trench 131 may be the circuit layer formed of the electrically conductive metal. Alternatively, the trench 131 may concurrently expose the insulation layer and the circuit layer of the base substrate 110. The trench 131 may be formed outside of the connection pad 120 to surround the connection pad 120. That is, the trench 131 may be formed to surround the outside of the electronic device 160 that will be mounted later.

The opening portion 135 may be formed in an upper portion of the connection pad 120. The opening portion 135 may expose the connection pad 120 to form a space in which the bump 140 is to be formed later.

The trench 131 and the opening portion 135 may be separately or concurrently formed. For example, the trench 131 and the opening portion 135 may be formed by performing exposure and developing operations. Alternatively, the trench 131 and the opening portion 135 may be formed by using laser. That is, a method of forming the trench 131 and the opening portion 135 is not limited to a specific method, and may be easily selected by one of ordinary skill in the art from the well-known technologies.

Referring to FIG. 5, the bump 140 may be formed. The bump 140 may be formed on the connection pad 120. The bump 140 may be generally formed as a solder. The bump 140 may be formed by inserting a solder paste or a solder ball in the opening portion 135 of the solder resist layer 130 and performing a reflow. The bump 140 may function as electrically connecting the connection pad 120 and the electronic device (160 of FIG. 8) that will be mounted later.

Referring to FIG. 6, a roughness 137 may be formed in the solder resister layer 130. The roughness 137 may be formed by performing plasma etching or chemical etching on a surface of the solder resist layer 130. The roughness 137 may be concurrently formed an inner wall of the trench 131 as the roughness 137 is formed in the surface of the solder resist layer 130.

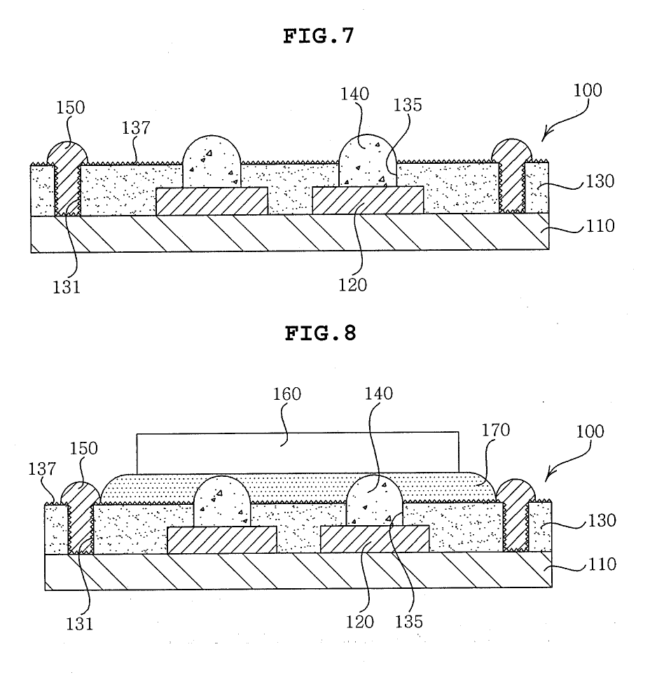

Referring to FIG. 7, the dam 150 may be formed. The dam 150 may be formed by coating the inside of the trench 131 with dam ink. The dam ink may be formed of a liquid solder resist material. The dam ink may be coated using an inkjet printing method. In this regard, the dam ink may bury the inside of the trench 131 and concurrently may be formed to protrude from an upper portion of the solder resist layer 130 at a predetermined height. The dam 150 may be formed by hardening the coated dam ink. The dam 150 formed using the inkjet printing method may have a hemispherical shape with an upper portion convex and curved. The above-formed dam 150 may be bonded to the surface of the solder resist layer 130 and the inner wall of the trench 131 in which the roughness 137 is formed. The dam 150 may be also bonded to at least one of the insulation layer and the circuit layer that are the surface of the base substrate 110. In this regard, the roughness 137 may be formed in the insulation layer or the circuit layer that is bonded to the dam 150. A bonding area between the dam 130 according to the embodiment of the present invention and the printed circuit board 100 may be maximized.

The dam 150 is bonded to the printed circuit board 100 in which the roughness 137 is formed at the maximum, which prevents the dam 150 from being detached, thereby enhancing reliability.

Referring to FIG. 8, the electronic device 160 may be mounted. The electronic device 160 may be mounted on the bump 140. The electronic device 160 may be bonded to the printed circuit board 100 through the bump 140. The electronic device 160 may be to electrically connected to the connection pad 120 through the bump 140. The underfill resin 170 may be injected after mounting the electronic device 160 on the bump 140. The underfill 170 may be injected between the electronic device 160 and the printed circuit board 100. In this regard, the underfill resin 170 in a liquid state may be prevented from being ejected to the outside owing to the dam 150 formed outside the electronic device 160.

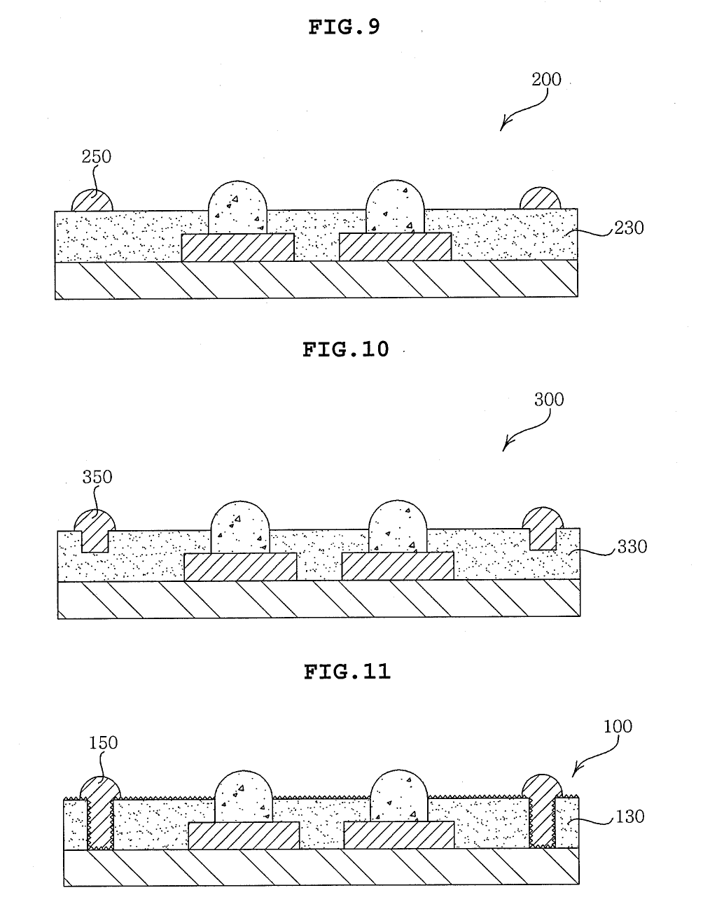

FIGS. 9 through 11 are exemplary views for comparing an adhesion test result of a dam.

The adhesion test of FIGS. 9 through 11 may be conducted by evaluating a pencil hardness of the dam. The pencil hardness may be evaluated by comparing a hardness (9H to 6B) of a pencil lead of KS G2603 and a hardness of the dam by using a pencil hardness test equipment. This comparison may be made by scraping the pencil lead against a surface of the dam at an angle of 45 with a uniform load and speed. The stronger the pencil hardness of the dam, the higher the hardness and adhesion of the dam. The pencil hardness may be classified as 9H, 8H, 7H, 6H, 5H, 4H, 3H, 2H, H, F, B, 2B, 3B, 4B, 5B, and 6B. In this regard, 9H is the strongest hardness, and hardness sequentially becomes low toward 6B.

FIG. 9 is an exemplary view of a printed circuit board in which a dam 250 is formed according to an embodiment of the prior art.

Referring to FIG. 9, the dam 250 according to the prior art may be formed on a solder resist layer 230. In this regard, a lower surface of the dam 250 may be bonded to only an upper portion of the solder resist layer 230. A pencil hardness of the dam 250 may be from 2B to H.

FIG. 10 is an exemplary view of a printed circuit board in which a dam 350 is formed according to another embodiment of the prior art.

Referring to FIG. 10, the dam 350 according to the prior art may be formed on a solder resist layer 330. The dam 350 may be inserted into the solder resist layer 330. In this regard, a lower surface of the dam 350 may be inserted into the center of the solder resist layer 330. A pencil hardness of the dam 350 may be from 2H to 4H.

FIG. 11 is an exemplary view of a printed circuit board in which a dam 150 is formed according to an embodiment of the present invention.

Referring to FIG. 11, the dam 150 may be formed on the solder resist layer 130. The dam 350 may be inserted into the solder resist layer 130. In this regard, the dam 350 may be formed passing through the solder resist layer 130. That is, a lower surface of the dam 150 may be bonded to a surface of the base substrate 110. A pencil hardness of the dam 150 may be from 7H to 8H.

As a result of comparing FIGS. 9 through 11, it may be confirmed that a bonding area between the dam 130 of FIG. 11 according to the embodiment of the present invention and the printed circuit board 100 structurally increases. The greater the bonding area between the dam 130 and the printed circuit board 100, the higher the adhesion therebetween. This may be confirmed from the test result that the pencil hardness of the dams 230 and 330 according to the prior art is between 2B and H and between 2H and 4H, whereas the pencil hardness of the dam 150 according to an embodiment of the present invention is between 8H and 9H.

As described above, a printed circuit board and a method of manufacturing the same according to the embodiments of the present invention can form a dam having an enhanced adhesion.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a base substrate in which a connection pad is formed;
a solder resist layer formed on the base substrate and including a trench exposing a surface of the base substrate; and
a dam formed on the solder resist layer and burying the inside of the trench.

2. The printed circuit board as set forth in claim 1, wherein a roughness is formed in an upper portion of the solder resist layer and an inner wall of the trench.

3. The printed circuit board as set forth in claim 1, wherein the surface of the base substrate exposed by the trench exposes at least one of an insulation layer and a circuit pattern of the base substrate.

4. The printed circuit board as set forth in claim 1, wherein the solder resist layer further includes an opening portion exposing the connection pad to the outside.

5. The printed circuit board as set forth in claim 4, further comprising a bump formed on the connection pad.

6. The printed circuit board as set forth in claim 4, further comprising an electronic device mounted on the bump.

7. The printed circuit board as set forth in claim 6, further comprising underfill resin injected between the electronic device and the base substrate.

8. The printed circuit board as set forth in claim 1, wherein an upper portion of the dam is formed in a semispherical shape.

9. A method of manufacturing a printed circuit board, the method comprising:
providing a base substrate in which a connection pad is formed;
forming a solder resist layer including a trench exposing a surface of the base substrate on the base substrate; and
forming a dam on the solder resist layer and burying the inside of the trench.

10. The method as set forth in claim 9, wherein the forming of the solder resist layer includes:
stacking the solder resist layer on the base substrate; and
removing the solder resist layer from a location at which the dam is to be formed and forming the trench exposing the surface of the base substrate.

11. The method as set forth in claim 9, further comprising, after the forming of the solder resist layer, forming a bump on the connection pad.

12. The method as set forth in claim 11, further comprising, before the forming of the bump, forming an opening portion in the solder resist layer so as to allow the connection pad to be exposed to the outside.

13. The method as set forth in claim 9, further comprising, after the forming of the solder resist layer, forming a roughness in an upper portion of the solder resist layer and an inner wall of the trench.

14. The method as set forth in claim 13, wherein in the forming of the roughness, the roughness is formed using a plasma polishing method or a chemical polishing method.

15. The method as set forth in claim 9, wherein in the forming of the dam, the dam is formed by filling and curing the inside of the trench with dam ink.

16. The method as set forth in claim 11, further comprising, after the forming of the bump, mounting an electronic device on the bump.

17. The method as set forth in claim 16, further comprising injecting underfill resin between the electronic device and the base substrate.

18. The method as set forth in claim 15, wherein in the forming of the dam, the dam ink is filled inside the trench using an inkjet printing method.

19. The method as set forth in claim 9, wherein an upper portion of the dam is formed in a semispherical shape.

20. The method as set forth in claim 9, wherein, in the forming of the solder resist layer, the surface of the base substrate exposed by the trench exposes at least one of an insulation layer and a circuit pattern of the base substrate.
